(19) United States
(12) Patent Application Publication
(10) Pub. No.: US 2007/0235788 A1
(43) Pub. Date: Oct. 11, 2007

(54) Poly-Insulator-Poly Capacitor and Fabrication Method for Making the Same

(76) Inventor: Ching-Hung Kao, Hsin-Chu Hsien (TW)

Correspondence Address: NORTH AMERICA INTELLECTUAL PROPERTY CORPORATION, P.O. BOX 506, MERRIFIELD, VA, 22116, US

(21) Appl. No.: 11/278,548

(22) Filed: Apr. 4, 2006

(51) Int. Cl. H01L 27/108; H01L 29/94; H01L 29/76; H01L 31/119

(52) U.S. Cl. 257/303

(57) ABSTRACT

A poly-insulator-poly (PIP) capacitor includes a first polysilicon plate; a first capacitor dielectric layer disposed on the first polysilicon plate; a second polysilicon plate stacked on the first capacitor dielectric layer, wherein the first polysilicon plate, the first capacitor dielectric layer, and the second polysilicon plate constitute a lower capacitor; a second capacitor dielectric layer disposed on the second polysilicon plate; and a third polysilicon plate stacked on the second capacitor dielectric layer, wherein the second polysilicon plate, the second capacitor dielectric layer, and the third polysilicon plate constitute an upper capacitor. Preferably, the first polysilicon plate and the third polysilicon plate are electrically connected to a first terminal of the PIP capacitor, while the second polysilicon plate is electrically connected to a second terminal of the PIP capacitor.

### BACKGROUND OF THE INVENTION

1. Field of the Invention

The present invention relates to a poly-insulator-poly (PIP) capacitor, and more particularly, to a PIP capacitor having high capacitance density and fabrication method for making the same.

2. Description of the Prior Art

Capacitors are elements that are used extensively in semiconductor devices for storing an electrical charge. Capacitors essentially comprise two conductive electrodes separated by an insulator. The capacitance, or amount of charge held by the capacitor per applied voltage, depends on a number of parameters such as the area of the electrodes, the distance between the electrodes, and the dielectric constant value for the insulator between the electrodes, as examples.

It is common for capacitors, as well as resistors, transistors, diodes, and other circuit elements, to be formed in semiconductor integrated circuits (IC's) of various types. Capacitors formed within analog integrated circuit fabrications typically assure proper operation of those analog integrated circuits, for example. Capacitors formed within digital integrated circuits typically provide storage locations for individual bits of digital data. Capacitors are used in filters, analog-to-digital converters, memory devices, control applications, and many other types of semiconductor devices.

One type of capacitor is a poly-insulator-poly (PIP) capacitor, which is frequently used in mixed-mode devices and logic devices, as examples. PIP capacitors are used to store a charge in a variety of semiconductor devices. PIP capacitors are often used as node in a memory device, for example. A PIP capacitor is typically formed horizontally on a semiconductor wafer, with two polysilicon electrodes sandwiching a dielectric layer parallel to the wafer surface.

A PIP capacitor formed within an integrated circuit usually comprises a double layer polysilicon capacitor. Double layer polysilicon capacitors are formed from two substantially planar conductive polysilicon electrodes separated by a dielectric layer. Double layer polysilicon capacitors provide several advantages when used within integrated circuits. For example, double layer polysilicon capacitors may easily be formed within several locations within an IC.

Please refer to FIG. 1 and FIG. 2. FIG. 1 and FIG. 2 are schematic views of forming a PIP capacitor 96 on a semiconductor wafer 80 according to the prior art. As shown in FIG. 1, the semiconductor wafer 80 includes a substrate (not shown) and a dielectric layer 82 disposed on the substrate. Next, a bottom plate 84 composed of a first polysilicon layer is evenly formed on a surface of the dielectric layer 82, in which the first polysilicon layer may be doped by ion implantation, for example. Next, a dielectric layer 86 and a second polysilicon layer 88 are respectively deposited over the surface of the bottom plate 84. Next, a lithographic process is performed to define the patterns of an upper plate 88, and the excess portions of the second polysilicon layer 88 and the dielectric layer 86 are removed so as to finish the formation of the PIP capacitor 96.

Next, as shown in FIG. 2, an interpoly dielectric layer 90 is disposed on the dielectric layer 82 and the PIP capacitor 96, and a chemical mechanical polishing (CMP) process is performed to planarize the surface of the interpoly dielectric layer 90. Next, a photoresist layer (not shown) is coated on the surface of the interpoly dielectric layer 90, and a lithographic process is performed to define the position of a plurality of via holes 98. The excess portion of the photoresist layer is then removed, and a dry etching process is performed by utilizing the residual photoresist layer as a mask. The interpoly dielectric layer 90 that is not covered by the mask is removed so as to form the via holes 98. The residual photoresist layer is then stripped.

Next, a sputtering process is performed to form a metal layer (not shown) that fills the via holes 98. Subsequently, an etching back process or a chemical mechanical polishing process is performed to remove portions of the metal layer, such that a surface of the metal layer in the via holes 98 is aligned with a surface of the interpoly dielectric layer 90 to form a plurality of contact plugs 92. Next, a metal layer (not shown) is evenly deposited on the surface of the interpoly dielectric layer 90, and an etching process is performed to form a metal wire 94 on top of the contact plugs 92. The contact plugs 92 are utilized to electrically connect the metal wire 94 and the PIP capacitor 96.

However, the capacitance density of the above-mentioned prior art structure becomes insufficient as the demand for capacitors with high capacity increases. In order to increase the capacitance of the capacitor, the area of the electrodes or the distance between the electrodes of the PIP capacitor structure must be significantly increased, thereby increasing the size of the capacitor and the complexity of the fabrication process. In light of forgoing, there is a constant need to provide a new PIP capacitor structure that not only has high capacitance density but also is cost effective.

### SUMMARY OF THE INVENTION

It is therefore an objective of the present invention to provide an improved PIP capacitor structure and method for making the same.

It is therefore another aspect of the present invention to provide a PIP capacitor having doubled capacitance per unit capacitor and a method for fabricating the same.

According to the claimed invention, A poly-insulator-poly (PIP) capacitor includes a first polysilicon plate; a first capacitor dielectric layer disposed on the first polysilicon plate; a second polysilicon plate stacked on the first capacitor dielectric layer, wherein the first polysilicon plate, the first capacitor dielectric layer, and the second polysilicon plate constitute a lower capacitor; a second capacitor dielectric layer disposed on the second polysilicon plate; and a third polysilicon plate stacked on the second capacitor dielectric layer, wherein the second polysilicon plate, the second capacitor dielectric layer, and the third polysilicon plate constitute an upper capacitor. Preferably, the first polysilicon plate and the third polysilicon plate are electrically connected to a first terminal of the PIP capacitor, while the second polysilicon plate is electrically connected to a second terminal of the PIP capacitor.

According to another aspect of the claimed invention, a method for fabricating a poly-insulator-poly (PIP) capacitor includes the steps of: providing a substrate; forming, in the order of, a first polysilicon layer, a first dielectric layer, a second polysilicon layer, a second dielectric layer, and a third polysilicon layer over the substrate; etching the third polysilicon layer, the second dielectric layer, the second polysilicon layer, and the first dielectric layer to form an upper capacitor structure consisting of a second polysilicon plate, a second capacitor dielectric layer, and a third polysilicon plate; partially covering the upper capacitor structure with a photomask that defines a first polysilicon plate to formed in the underlying first polysilicon layer ; simultaneously etching the first polysilicon layer and a portion of the third polysilicon layer of the upper capacitor structure that are not covered by the photomask; and stripping the photomask.

Preferably, by forming two dielectric layers between three polysilicon layers, the present invention is able to provide a PIP capacitor having doubled capacitance per unit capacitor while significantly reducing the area of the capacitor. Despite the capacitance of the capacitor is doubled, the number of photomasks utilized during the fabrication process is not increased while comparing to the prior art. Ultimately, by increasing the capacitance density of the capacitor while reducing the area needed for fabrication, the present invention is able to significantly increase the yield and overall production of the product.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 and FIG. 2 are schematic views of forming a PIP capacitor on a semiconductor wafer according to the prior art.

FIG. 3 is a perspective diagram illustrating a PIP capacitor according to a preferred embodiment of the present invention.

FIG. 4 through FIG. 13 are perspective diagrams illustrating the means of fabricating the PIP capacitor as set forth in FIG. 1 according to the preferred embodiment of the present invention.

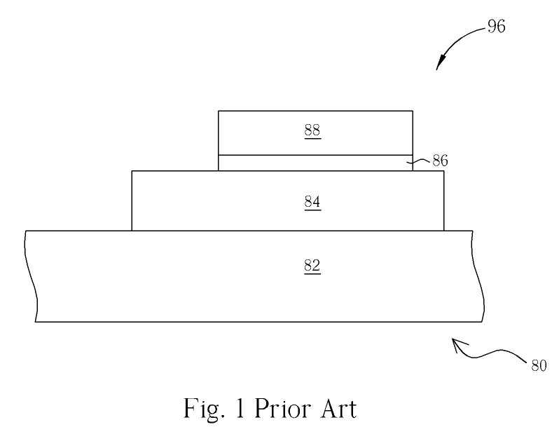

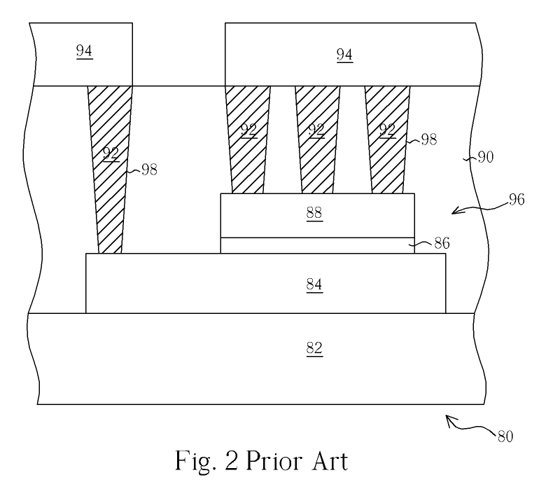

### DETAILED DESCRIPTION

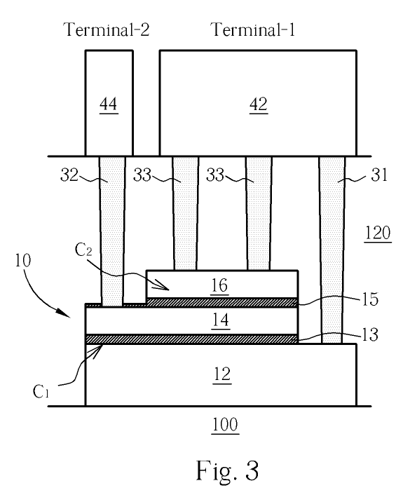

Please refer to FIG. 3. FIG. 3 is a perspective diagram illustrating a PIP capacitor 10 according to a preferred embodiment of the present invention. As shown in FIG. 3, the PIP capacitor 10 includes a first polysilicon plate 12, which maybe defined on a base layer 100 such as an interpoly dielectric layer, but not limited thereto. A second polysilicon plate 14, which is thinner than the first polysilicon plate 12, is stacked above the first polysilicon plate 12 and is electrically isolated from the first polysilicon plate 12 with a first capacitor dielectric layer 13. A third polysilicon plate 16 is stacked above the second polysilicon plate 14 and is electrically isolated from the second polysilicon plate 14 with a second capacitor dielectric layer 15. Preferably, the first polysilicon plate 12 is composed of a polysilicon layer or a combination of a polysilicon layer and a polycide layer, such as a tungsten silicide (WSi) layer. The second polysilicon plate 14 is composed of a polysilicon layer, a tungsten silicide layer, or a combination of a polysilicon layer and a tungsten silicide layer. Similarly, the third polysilicon plate 16 is composed of a polysilicon layer, a tungsten silicide layer, or a combination of a polysilicon layer and a tungsten silicide layer.

Additionally, the first capacitor dielectric layer 13 and the second capacitor dielectric layer 15 are composed of oxide-nitride-oxide, and the polysilicon layer of the first polysilicon plate 12, the second polysilicon plate 14, and the third polysilicon plate 16 are doped by an ion implantation process. The above-mentioned PIP capacitor 10 is covered with an interpoly dielectric layer 120. The first polysilicon plate 12, the first capacitor dielectric layer 13, and the second polysilicon plate 14 constitute a first capacitor (C₁) or a lower capacitor. The second polysilicon plate 14, the second capacitor dielectric layer 15, and the third polysilicon plate 16 constitute a second capacitor (C₂) or an upper capacitor.

A plurality of conductive vias are formed in the interpoly dielectric layer 120. The first polysilicon plate 12 of the above-mentioned PIP capacitor 10 is electrically connected to a first conductive terminal 42 through at least one conductive via 31 that penetrate through the interpoly dielectric layer 120. The second polysilicon plate 14 is electrically connected to a second conductive terminal 44 through at least one conductive via 32. The third polysilicon plate 16 is electrically connected to the first conductive terminal 42 through at least one conductive via 33 that penetrates through the interpoly dielectric layer 120. Preferably, the present invention features a sandwich-like PIP capacitor structure consists of the lower capacitor C₁ and the upper capacitor C₂. The first polysilicon plate 12, namely, one electrode of the lower capacitor C₁, is electrically coupled to the third polysilicon plate 16, namely, one electrode of the upper capacitor C₂. The second polysilicon plate 14 serves as a common electrode of the lower capacitor C₁ and the upper capacitor C₂ and is interposed between the first polysilicon plate 12 and the third polysilicon plate 16.

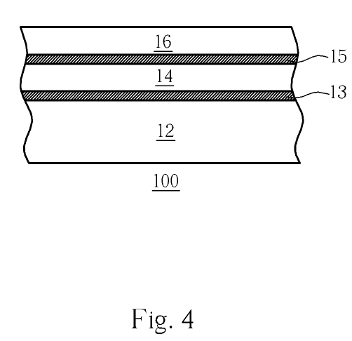

Please refer to FIG. 4 through FIG. 13. FIG. 4 through FIG. 13 are perspective diagrams illustrating the means of fabricating the PIP capacitor 10 as set forth in FIG. 3 according to the preferred embodiment of the present invention, in which like reference numerals refer to similar or corresponding elements, regions, and portion. As shown in FIG. 4, a substrate (not shown) having thereon a base layer 100 is first provided, in which the base layer 100 is an interpoly dielectric layer, but not limited thereto. Next, a first polysilicon layer 12, a first capacitor dielectric layer 13, a second polysilicon layer 14, a second capacitor dielectric layer 15, and a third polysilicon layer 16 are sequentially deposited on the based layer 100, in which the first polysilicon layer 12, the second polysilicon layer 14, and the third polysilicon layer 16 may be doped by an ion implantation process. As described previously, the first polysilicon layer 12 is composed of a polysilicon layer or a combination of a polysilicon layer and a polycide layer, such as a tungsten silicide (WSi) layer. The second polysilicon plate 14 is composed of a polysilicon layer, a tungsten silicide layer, or a combination of a polysilicon layer and a tungsten silicide layer, and the third polysilicon plate 16 is composed of a polysilicon layer, a tungsten silicide layer, or a combination of a polysilicon layer and a tungsten silicide layer. Additionally, the thickness of the first polysilicon layer 12 is greater than the thickness of the second polysilicon layer 14, and the first capacitor dielectric layer 13 and the second capacitor dielectric layer 15 are both composed of PECVD dielectric materials.

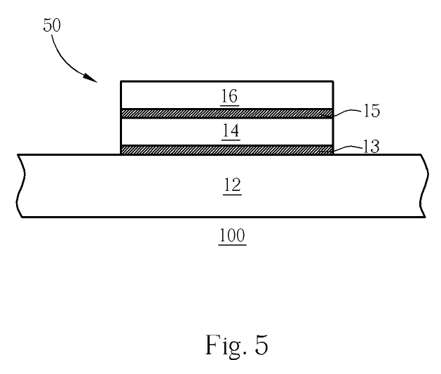

As shown in FIG. 5, a lithographic process and an anisotropic dry etching process are performed to form an upper capacitor stack 50 consisting of the first capacitor dielectric layer 13, the second polysilicon plate 14, the second capacitor dielectric layer 15, and the third polysilicon plate 16. The upper capacitor stack 50 is defined on the first polysilicon layer 12. In other words, after etching through the first capacitor dielectric layer 13, the dry etching stops on the first polysilicon layer 12.

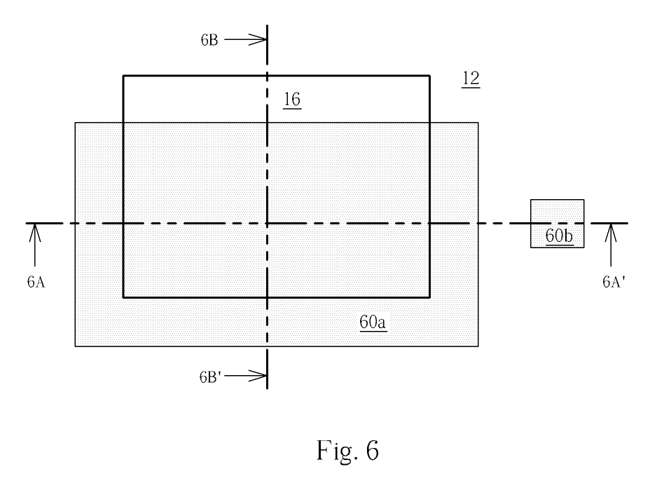

As shown in FIG. 6, a top view presenting a photomask 60a, the first polysilicon layer 12, and the perspective third polysilicon plate 16 of the upper capacitor stack 50 is illustrated. As indicated in FIG. 6, the photomask 60a covers most portion of the upper capacitor stack 50. A small portion of the third polysilicon plate 16 of the upper capacitor stack 50 is therefore exposed and will be etched away in the following etching process.

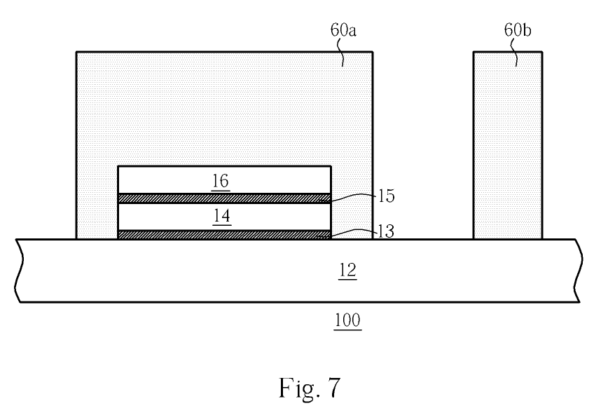

As shown in FIG. 7, a perspective view of the capacitor structure along the line 6A6A′ of FIG. 6, a photoresist layer (not shown) is coated on the first polysilicon layer 12 and covering the upper capacitor stack 50. Preferably, the photoresist layer is subjected to exposure and development procedures, thereby forming photomasks 60a and 60b, such that the photomask 60a defines the pattern and dimension of the first polysilicon layer 12 that serves as one electrode of a lower capacitor to be formed, while the photomask 60b defines a conductive pattern of the first polysilicon layer 12.

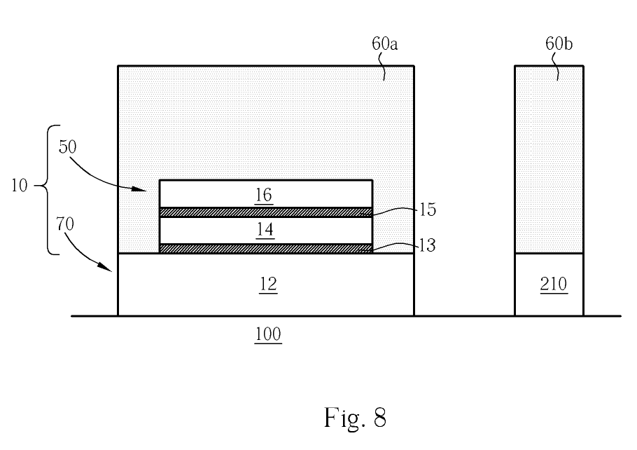

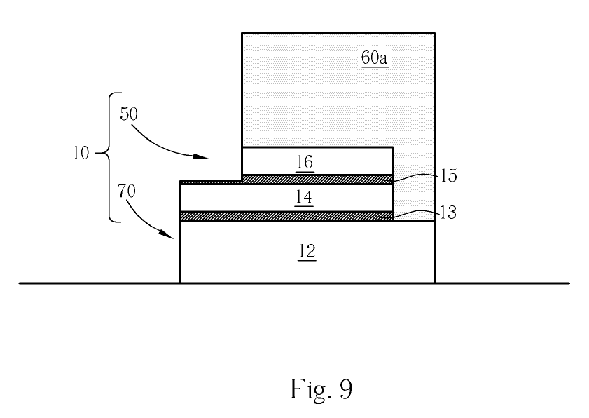

As shown in FIG. 8, a dry etching process is performed to etch the first polysilicon layer 12 that is not covered by the photomasks 60a and 60b to form a lower capacitor stack 70 and a pattern 210, such as a gate as according to the preferred embodiment of the present invention. Alternatively, the pattern 210 can also be utilized as a word line, a wiring line, a fuse, or a resistor according to different fabrication processes. The upper capacitor stack 50 and the lower capacitor stack 70, which consist of the first polysilicon plate 12, the first capacitor dielectric layer 13, and the second polysilicon plate 14, together constitute a sandwiched capacitor structure 10. Referring briefly to FIG. 9, a perspective view of the sandwiched capacitor structure 10 along the line 6B6B′ of FIG. 6 and the photomask 60a thereon is illustrated. As shown in FIG. 9, a portion of the third polysilicon plate 16 of the upper capacitor stack 50 that is not covered by the photomask 60a is etched away in this dry etching process. By utilizing the third polysilicon plate 16 as an etching buffer, the dry etching process can be stopped on the second capacitor dielectric layer 15. In another case, the second capacitor dielectric layer 15 may be further etched through and the dry etching stops on the second polysilicon plate 14. Hence, as shown in FIG. 9, the surface area of the third polysilicon plate 16 is smaller than the surface area of the second polysilicon plate 14, and the surface area of the second polysilicon plate 14 is also smaller than the surface area of the first polysilicon plate 12.

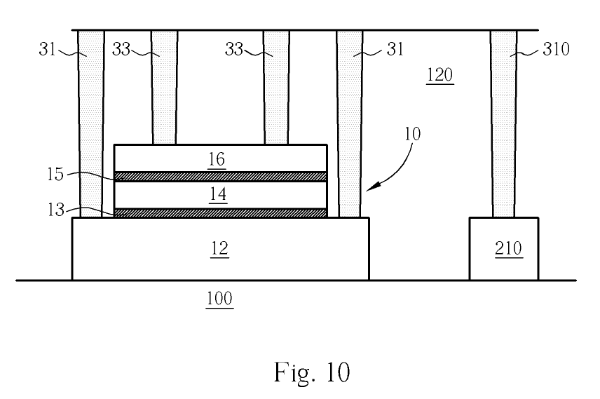

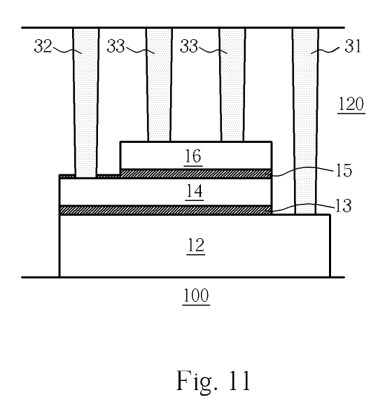

As shown in FIG. 10 and FIG. 11, in which FIG. 11 shows a 90-degree rotated view of the capacitor structure 10 of FIG. 10, after stripping the photomasks, an interpoly dielectric layer 120 is deposited on the capacitor structure 10, the base layer 10, and the pattern 210. The interpoly dielectric layer 120 may be formed by chemical vapor deposition (CVD) or other suitable processes. Subsequently, a plurality of contact plugs 31, 32, 33, and 310 are formed in the interpoly dielectric layer 120, in which the contact plug 31 is electrically connected to the first polysilicon plate 12, the contact plugs 33 are electrically connected to the second polysilicon plate 14 (as shown in FIG. 11), the contact plugs 33 are electrically connected to the third polysilicon plate 16, and the contact plug 310 is electrically connected to the pattern 210.

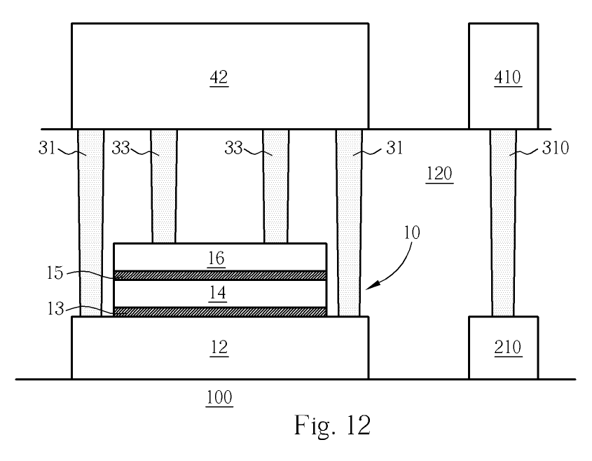

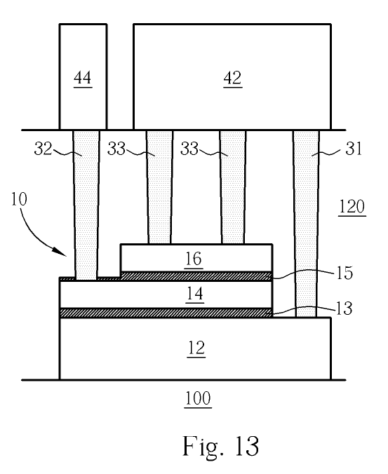

As shown in FIG. 12 and FIG. 13, in which FIG. 13 shows a 90-degree rotated view of the capacitor structure 10 of FIG. 12, a first conductive terminal 42 and a second conductive terminal 44 are formed above the capacitor structure 10 on the interpoly dielectric layer 120. A fourth level interconnection line 410 is also defined above the contact plug 310. The first conductive terminal 42 is electrically connected to the first polysilicon plate 12 and the third polysilicon plate 16 through the contact plugs 31 and 33 respectively. The second polysilicon plate 14 of the capacitor structure 10 is electrically connected to the second conductive terminal 44 through the contact plug 32, as shown in FIG. 13.

Preferably, by forming two dielectric layers between three polysilicon layers, the present invention is able to provide a PIP capacitor having doubled capacitance per unit capacitor, thereby significantly reducing the area of the capacitor. Despite the capacitance of the capacitor is doubled, the number of photomasks utilized during the fabrication process is not increased while comparing to the prior art. Ultimately, by increasing the capacitance density of the capacitor while reducing the area needed for fabrication, the present invention is able to significantly increase the yield and overall production of the product.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A poly-insulator-poly (PIP) capacitor, comprising:
a first polysilicon plate;
a first capacitor dielectric layer disposed on the first polysilicon plate;
a second polysilicon plate stacked on the first capacitor dielectric layer, wherein the first polysilicon plate, the first capacitor dielectric layer, and the second polysilicon plate constitute a lower capacitor;
a second capacitor dielectric layer disposed on the second polysilicon plate; and
a third polysilicon plate stacked on the second capacitor dielectric layer, wherein the second polysilicon plate, the second capacitor dielectric layer, and the third polysilicon plate constitute an upper capacitor;
and wherein the first polysilicon plate and the third polysilicon plate are electrically connected to a first terminal of the PIP capacitor, while the second polysilicon plate is electrically connected to a second terminal of the PIP capacitor.

2. The PIP capacitor of claim 1, wherein the surface area of the second polysilicon plate is less than the surface area of the first polysilicon plate.

3. The PIP capacitor of claim 1, wherein the surface area of the third polysilicon plate is less than the surface area of the second polysilicon plate.

4. The PIP capacitor of claim 1, wherein the first capacitor dielectric layer comprises PECVD dielectric.

5. The PIP capacitor of claim 1, wherein the second capacitor dielectric layer comprises PECVD dielectric.

6. The PIP capacitor of claim 1, wherein the thickness of the second polysilicon plate is less than the thickness of the first polysilicon plate.

7. The PIP capacitor of claim 1, wherein the first polysilicon plate, the second polysilicon plate, and the third polysilicon plate comprise doped polysilicon.

8. The PIP capacitor of claim 1, wherein the first polysilicon plate comprises a polysilicon layer or a combination of a polysilicon layer and a tungsten silicide (WSi) layer.

9. The PIP capacitor of claim 1, wherein the second polysilicon plate comprises a polysilicon layer, a tungsten silicide layer, or a combination of a polysilicon layer and a tungsten silicide layer.

10. The PIP capacitor of claim 1, wherein the third polysilicon plate comprises a polysilicon layer, a tungsten silicide layer, or a combination of a polysilicon layer and a tungsten silicide layer.

11. A method for fabricating a poly-insulator-poly (PIP) capacitor, comprising:
providing a substrate;
forming, in the order of, a first polysilicon layer, a first dielectric layer, a second polysilicon layer, a second dielectric layer, and a third polysilicon layer over the substrate;
etching the third polysilicon layer, the second dielectric layer, the second polysilicon layer, and the first dielectric layer to form an upper capacitor structure consisting of a second polysilicon plate, a second capacitor dielectric layer, and a third polysilicon plate;
partially covering the upper capacitor structure with a photomask that defines a first polysilicon plate to formed in the underlying first polysilicon layer;
simultaneously etching the first polysilicon layer and a portion of the third polysilicon layer of the upper capacitor structure that are not covered by the photomask; and
stripping the photomask.

12. The method for fabricating a PIP capacitor of claim 11, wherein the surface area of the second polysilicon plate is less than the surface area of the first polysilicon plate.

13. The method for fabricating a PIP capacitor of claim 11, wherein the surface area of the third polysilicon plate is less than the surface area of the second polysilicon plate.

14. The method for fabricating a PIP capacitor of claim 11, wherein the first capacitor dielectric layer comprises PECVD dielectric.

15. The method for fabricating a PIP capacitor of claim 11, wherein the second capacitor dielectric layer comprises PECVD dielectric.

16. The method for fabricating a PIP capacitor of claim 11, wherein the thickness of the second polysilicon plate is less than the thickness of the first polysilicon plate.

17. The method for fabricating a PIP capacitor of claim 11, wherein the first polysilicon plate, the second polysilicon plate, and the third polysilicon plate comprise doped polysilicon layers.

18. The method for fabricating a PIP capacitor of claim 11, wherein the first polysilicon layer comprises a polysilicon layer or a combination of a polysilicon layer and a tungsten silicide (WSi) layer.

19. The method for fabricating a PIP capacitor of claim 11, wherein the second polysilicon layer comprises a polysilicon layer, a tungsten silicide layer, or a combination of a polysilicon layer and a tungsten silicide layer.

20. The method for fabricating a PIP capacitor of claim 11, wherein the third polysilicon layer comprises a polysilicon layer, a tungsten silicide layer, or a combination of a polysilicon layer and a tungsten silicide layer.
